(19) United States
(12) Patent Application Publication
(10) Pub. No.: US 2024/0347413 A1
(43) Pub. Date: Oct. 17, 2024

(54) THERMALLY REGULATED SEMICONDUCTOR DEVICE

(71) Applicant: Micron Technology, Inc., Boise, ID (US)

(72) Inventors: Chen Yu Huang, Taichung (TW); Chong Leong Gan, Taichung (TW)

(21) Appl. No.: 18/605,034

(22) Filed: Mar. 14, 2024

Related U.S. Application Data
(60) Provisional application No. 63/458,595, filed on Apr. 11, 2023.

(51) Int. Cl. H01L 23/373; H01L 23/00; H01L 23/31; H01L 23/498; H01L 25/10; H10B 80/00

(52) U.S. Cl. CPC H01L 23/373; H01L 23/3178; H01L 23/49827; H01L 24/05; H01L 24/16; H01L 25/105; H01L 24/48; H01L 2224/05147; H01L 2224/16148; H01L 2224/48147; H01L 2224/48229; H01L 2225/1052; H01L 2225/1094; H01L 2924/1431; H10B 80/00

(57) ABSTRACT

A semiconductor device assembly is provided. The semiconductor device assembly can include a substrate and one or more semiconductor dies. The semiconductor device assembly can further include a thermally conductive material (e.g., carbon nanotubes, graphene) capable of dissipating heat from the semiconductor device assembly. In doing so, a thermally regulated semiconductor device can be assembled.

### CROSS-REFERENCE TO RELATED APPLICATION(S)

The present application claims priority to U.S. Provisional Patent Application No. 63/458,595, filed Apr. 11, 2023, the disclosure of which is incorporated herein by reference in its entirety.

### TECHNICAL FIELD

The present disclosure generally relates to semiconductor device assemblies and more particularly relates to a thermally regulated semiconductor device.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly that includes a thermally conductive via extending through an encapsulant.

FIG. 2 illustrates a simplified schematic cross-sectional view of a semiconductor device assembly that includes thermally conductive material implemented within a conductive pillar.

FIGS. 3A-3C illustrate simplified schematic cross-sectional views of a series of steps for fabricating a semiconductor device assembly that includes thermally conductive material implemented within a conductive pillar.

FIG. 4 illustrates a simplified schematic cross-sectional view of a semiconductor device assembly that includes interconnects formed from thermally conductive material.

FIGS. 5A-5E illustrate simplified schematic cross-sectional views of a series of steps for fabricating a semiconductor device assembly that includes a thermally conductive encapsulant.

FIG. 6 illustrates a schematic view of a system that includes a semiconductor device assembly configured in accordance with an embodiment of the present technology.

FIG. 7 illustrates a method of fabricating a semiconductor device assembly that includes a thermally conductive via extending through an encapsulant.

FIG. 8 illustrates a method of fabricating a semiconductor device assembly that includes thermally conductive material implemented within a conductive pillar.

FIG. 9 illustrates a method of fabricating a semiconductor device assembly that includes interconnects formed from thermally conductive material.

FIG. 10 illustrates a method of fabricating a semiconductor device assembly that includes a thermally conductive encapsulant.

### DETAILED DESCRIPTION

Semiconductor devices are integrated into many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques for increasing the number of circuit elements on a semiconductor device without simultaneously increasing the size of the device. This increase in circuit density, however, can limit the ability to adequately dissipate heat generated during operation of the semiconductor device, which can impact the performance of the device. As a result, additional techniques may be needed to dissipate greater amounts of heat from a semiconductor device.

One such technique is to implement thermally conductive material (e.g., carbon nanotubes, graphene) within a semiconductor device assembly. A semiconductor device assembly can include a substrate and one or more semiconductor dies. In some cases, thermally conductive material can be implemented within interconnects that electrically couple a semiconductor die to the substrate or another semiconductor die. In some implementations, the thermally conductive material can be implemented as an encapsulant that at least partially surrounds the one or more semiconductor dies. In yet another aspect, the thermally conductive material can be implemented as vias that extend through an encapsulant (e.g., mold resin) that at least partially encapsulates the one or more semiconductor dies. In general, however, the implementation of thermally conductive material within the semiconductor device assembly can dissipate heat from the semiconductor device, thereby improving the device's performance and reliability.

### Thermally Dissipative Throuqh-Encapsulant Via

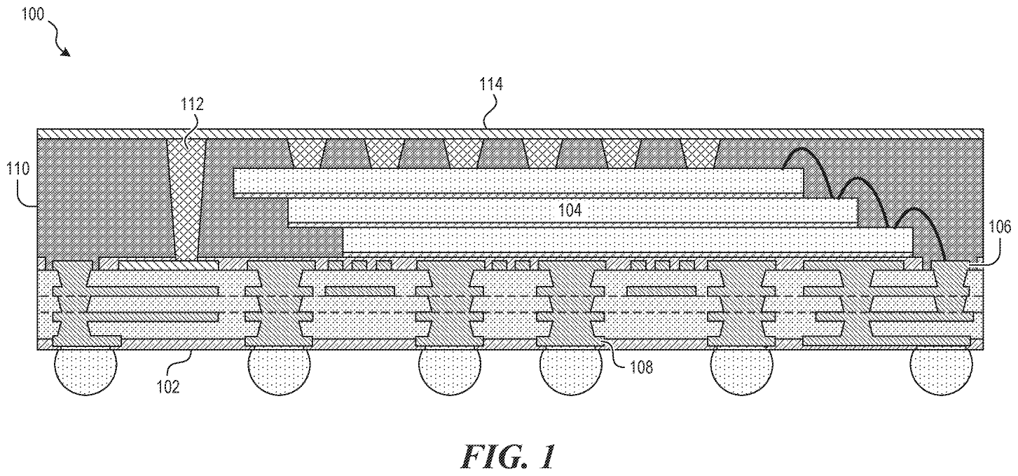

FIG. 1 illustrates a simplified schematic cross-sectional view of a semiconductor device assembly 100 in accordance with an embodiment of the present technology. The semiconductor device assembly 100 includes a substrate 102 (e.g., printed-circuit board (PCB), interposer, semiconductor die) and one or more semiconductor dies 104 coupled to the substrate 102. The semiconductor dies 104 can electrically couple to the substrate 102 through interconnects coupled between contacts 106 (e.g., contact pads) at the substrate 102 and contacts (not shown) at the semiconductor dies 104. As illustrated, the interconnects are implemented as wires; however, the interconnects could be implemented as any connective element (e.g., wires, solder, conductive pillars). The substrate 102 can include traces, lines, vias, or other connective elements that extend between the contacts 106 at the upper surface of the substrate 102 and contacts 108 at the lower surface of the substrate 102. The contacts 108 can connect (e.g., through solder balls) to external components (e.g., a motherboard) to provide external connectivity (e.g., power, ground, input/output (I/O) signaling) to the semiconductor dies 104 through the contacts 106.

The semiconductor device assembly 100 includes an encapsulant 110 (e.g., mold resin) at least partially encapsulating the semiconductor dies 104 and the substrate 102. One or more through-encapsulant vias 112 including a thermally conductive material can extend at least partially through the encapsulant 110. In aspects, the portion of thermally conductive material may be referred to as “a through-encapsulant via” in reference to its similarities with a via used to communicate signaling within a semiconductor device. In contrast to a via used for communicating signaling, however, the through-encapsulant via 112 need not communicatively couple the components. Instead, the through-encapsulant via 112 can be used to dissipate heat away from the semiconductor device assembly 100. For example, the through-encapsulant via 112 can include a thermally conductive material capable of dissipating heat from the semiconductor device assembly 100. In some cases, the thermally conductive material may include carbon nanotubes or graphene due to the advantageous thermal properties of these materials. For instance, carbon nanotubes can have a longitudinal thermal conductivity between 2800 and 6000 Watts per meter-Kelvin, and graphene can have a thermal conductivity of approximately 4000 Watts per meter-Kelvin. In this way, carbon nanotubes or graphene can be approximately 15 times more effective at dissipating heat than copper.

The through-encapsulant vias 112 can extend from an upper surface of the encapsulant 110 and at least partially through the encapsulant 110. In some cases, the through-encapsulant vias 112 can extend entirely through the encapsulant 110 to the substrate 102. In this way, the through-encapsulant vias 112 can dissipate heat from the substrate 102 or the semiconductor dies 104. In some implementations, the through-encapsulant vias 112 can extend through the encapsulant 110 to a surface (e.g., active surface at which circuitry is disposed) of one or more of the semiconductor dies 104 to improve heat dissipation from the semiconductor dies 104. The through-encapsulant vias 112 can be formed through various steps of removing and depositing material. For example, an opening can be formed in the encapsulant 110, and thermally conductive material can be disposed in the opening. Material can be removed through any appropriate technique to form the opening. As a specific example, laser drilling can be used to create the opening. Similarly, material can be disposed in the opening through any appropriate technique (e.g., dispensing). Some techniques for removing the material can form a tapered opening. As a result, the through-encapsulant vias 112 can be tapered from the upper surface of the encapsulant 110 such that a cross section of the through-encapsulant vias 112 along a plane closer to the substrate 102 is smaller than a cross section of the through-encapsulant vias 112 along a plane farther from the substrate 102.

The semiconductor device assembly 100 can further include a heat dissipating structure 114 disposed at the upper surface of the encapsulant 110. The heat dissipating structure 114 can include a thermally conductive material (e.g., carbon nanotubes, graphene, copper) capable of dissipating heat. The heat dissipating structure 114 can contact the through-encapsulant vias 112 to enable heat to dissipate from the through-encapsulant vias 112 to the heat dissipating structure 114. The heat dissipating structure 114 can have a surface exposed at an exterior of the semiconductor device assembly 100 to enable heat to dissipate from the semiconductor device assembly 100 through the exposed surface.

### Thermally Dissipative Interconnects

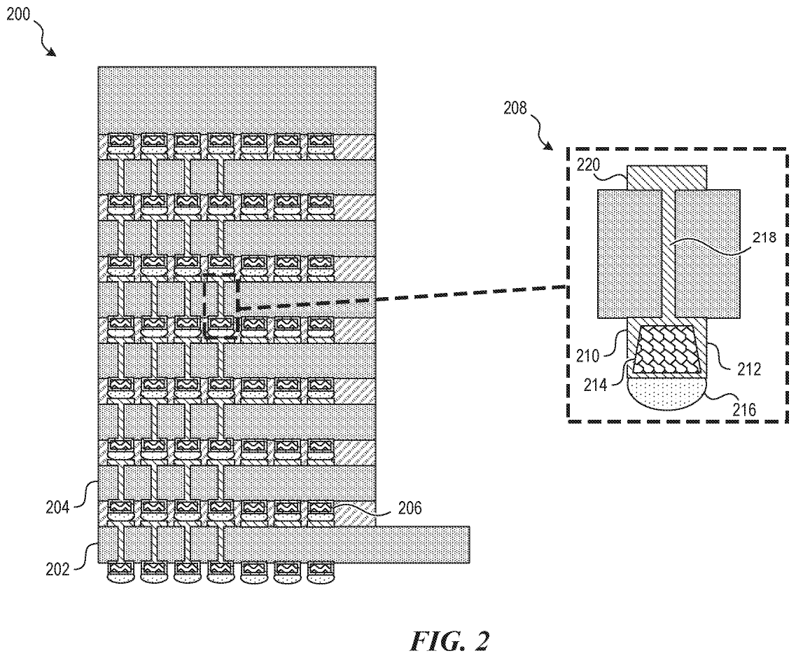

FIG. 2 illustrates a simplified schematic cross-sectional view of a semiconductor device assembly 200 in accordance with an embodiment of the present technology. The semiconductor device assembly 200 includes a substrate 202 (e.g., PCB, interposer, semiconductor die) and at least one semiconductor die 204. The substrate 202 and the semiconductor die 204 can be electrically coupled through interconnects 206. A zoomed view of the interconnects 206 and the connective elements within the semiconductor die 204 (or the substrate 202) is shown in the view 208.

As illustrated in the view 208, the semiconductor die 204 can include a conductive pillar 210 that extends from a first side (e.g., an active side at which circuitry is disposed) of the semiconductor die 204. The conductive pillar 210 can include a conductive material 212 (e.g., copper) and a thermally conductive material 214 (e.g., carbon nanotubes, graphene) capable of dissipating heat from the semiconductor device assembly 200. The conductive material 212 can implement a contact from which the conductive pillar 210 extends. The thermally conductive material 214 can be at least partially embedded within the conductive material 212 such that the conductive material 212 at least partially surrounds the thermally conductive material 214. In some cases, the thermally conductive material 214 can be entirely surrounded by the conductive material 212. The conductive material 212 can surround the thermally conductive material 214 at the sides of the conductive pillar 210 or at a distal end of the conductive pillar 210. In some implementations, the thermally conductive material 214 can be exposed at a distal portion (e.g., from the semiconductor die 204) of the conductive pillar 210. In other implementations, the conductive material 212 can surround the thermally conductive material 214 at a distal portion of the conductive pillar 210 to improve adhesion between the conductive pillar 210 and the solder 216 disposed at the distal portion of the conductive pillar 210. The solder 216 can be disposed at a distal portion of the conductive pillar 210 to enable interconnects to be formed between the substrate 202 and the at least one semiconductor die 204. The semiconductor die 204 can include a through-silicon via 218 that extends between the conductive pillar 210 (e.g., a contact from which the conductive pillar extends) and a contact 220 (e.g., contact pad) disposed at a second side of the semiconductor die 204 opposite the first side. As a result, additional semiconductor dies can be coupled to the semiconductor die 204 at the contact 220.

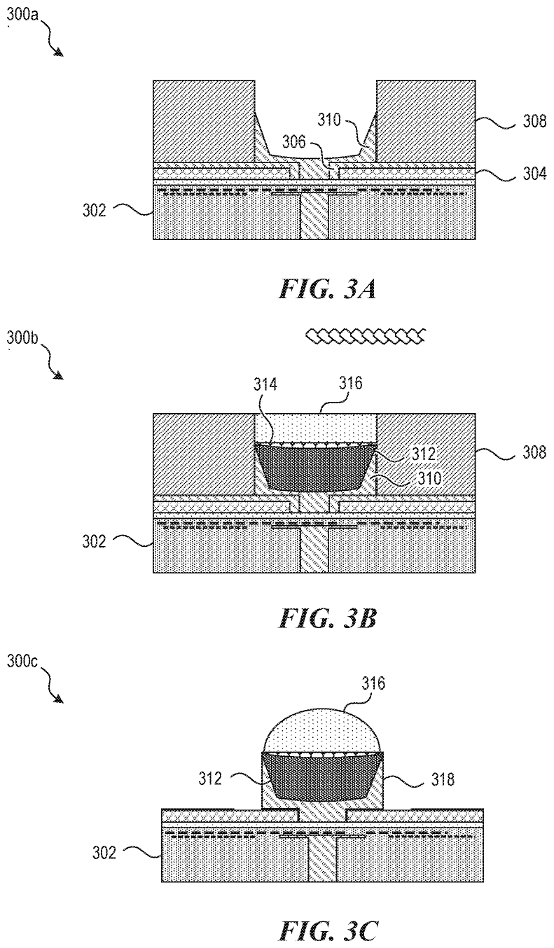

Various techniques can be used to fabricate a semiconductor device with a conductive pillar that includes a thermally conductive material. One example for fabricating such a semiconductor device assembly is illustrated in FIGS. 3A-3C. Specifically, FIG. 3A illustrates a simplified schematic cross-sectional view of a semiconductor device assembly 300a that includes a semiconductor die 302. The semiconductor die 302 includes a layer of dielectric material 304. A contact 306 (e.g., under bump metallization (UBM)) is exposed through an opening in the dielectric material 304 (e.g., silicon oxide, silicon carbide, silicon nitride, silicon carbon nitride). A photoresist 308 is disposed at the dielectric material 304 such that an opening in the photoresist 308 exposes the contact 306. Conductive material 310 (e.g., copper) is disposed at the opening in the photoresist 308, for example, through chemical vapor deposition (CVD). The conductive material 310 can implement a contact pad at the opening in the photoresist 308. In aspects, the conductive material 310 can cover a bottom surface exposed through the opening in the photoresist 308 and extend at least partially up the sidewalls of the photoresist 308. In this way, the conductive material 310 can create a basin at which thermally conductive material can be disposed, as illustrated in FIG. 3B.

FIG. 3B illustrates a simplified schematic cross-sectional view of a semiconductor device assembly 300b after thermally conductive material 312 (e.g., carbon nanotubes, graphene) is disposed at the conductive material 310. As illustrated, the thermally conductive material 312 is disposed (e.g., dispensed) in the opening of the photoresist 308 at the conductive material 310. In some cases, the thermally conductive material 312 can be disposed only within the basin created by the conductive material 310. In doing so, the thermally conductive material 312 can be entirely surrounded by the conductive material 310. In other cases, the thermally conductive material 312 can be disposed beyond the basin created by the conductive material 310. An additional portion of conductive material 314 (e.g., copper) can be disposed in the opening at the thermally conductive material 312, and solder 316 can be disposed in the opening at the additional portion of conductive material 314. In other implementations, the additional portion of conductive material 314 is not disposed at the thermally conductive material 312. In this way, the thermally conductive material 312 can directly interface with the solder 316. The photoresist 308 can then be removed, as illustrated in FIG. 3C.

FIG. 3C illustrates a simplified schematic cross-sectional view of a semiconductor device assembly 300c after the photoresist is removed to leave a conductive pillar 318 extending from the semiconductor die 302. In aspects, the photoresist can be removed through chemical or mechanical etching. Once the photoresist is removed, the conductive pillar 318 can extend from the semiconductor die 302. The conductive pillar 318 can include the thermally conductive material 312. The solder 316 can be disposed at a distal portion of the conductive pillar 318 to enable electrical connection between the semiconductor die 302 and one or more additional semiconductor dies. For example, the conductive pillar 318 could be aligned with a contact pad on an additional semiconductor die, and the solder 316 can be reflowed such that the conductive pillar 318 implements an interconnect between the semiconductor die 302 and the additional semiconductor die.

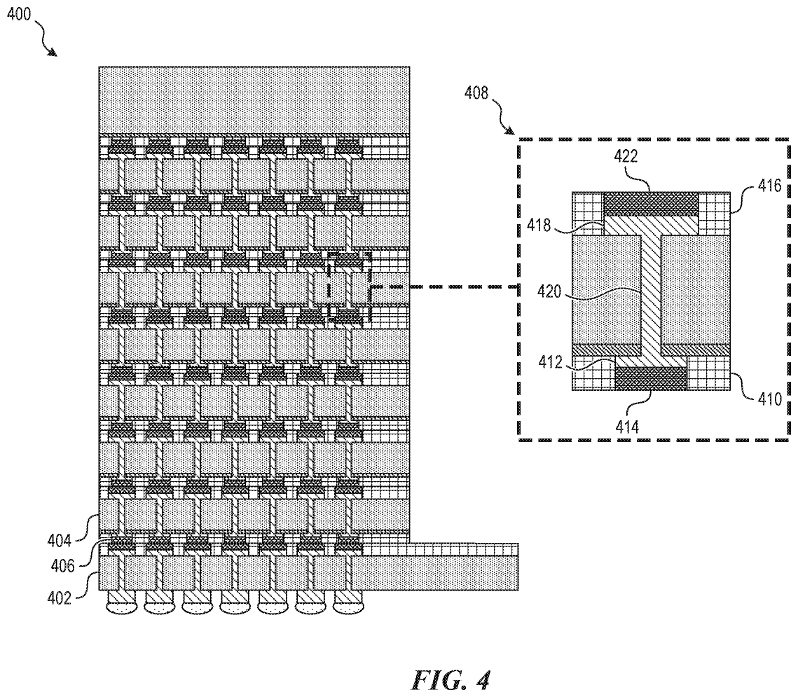

FIG. 4 illustrates a simplified schematic cross-sectional view of a semiconductor device assembly 400 in accordance with an embodiment of the present technology. The semiconductor device assembly 400 includes a substrate 402 (e.g., PCB, interposer, semiconductor die) and at least one semiconductor die 404. The substrate 402 and the semiconductor die 404 can be electrically coupled through interconnects 406. A zoomed view of the interconnects 406 and the connective elements within the semiconductor die 404 (or the substrate 402) is shown in the view 408.

As illustrated in the view 408, the semiconductor die 404 can include a layer of dielectric material 410 (e.g., silicon oxide, silicon carbine, silicon nitride, silicon carbon nitride) disposed at a first side (e.g., an active side at which circuitry is disposed) of the semiconductor die 404. The layer of dielectric material 410 includes an opening that exposes a contact 412 (e.g., contact pad). The contact 412 can be formed from a conductive material (e.g., copper). Thermally conductive material 414 (e.g., graphene) can be disposed in the opening at the contact 412. In some cases, the thermally conductive material 414 can be a material having a thermal expansion coefficient large enough to enable diffusion between adjacent metals. In aspects, the thermally conductive material 414 can be disposed such that an exposed surface of the thermally conductive material 414 is flush with an exposed surface of the layer of dielectric material 410.

The semiconductor die 404 can further include a layer of dielectric material 416 disposed at a second side of the semiconductor die 404 opposite the first side. The layer of dielectric material 416 can include an opening that exposes a contact 418 (e.g., contact pad) formed from conductive material (e.g., copper). The semiconductor die 404 can include a through-silicon via 420 that enables signals to be carried from the contact 412 to the contact 418, and vice versa. Thermally conductive material 422 (e.g., graphene) can be disposed in the opening at the contact 418.

An additional semiconductor die configured similarly to the semiconductor die 404 can be coupled to the semiconductor die 404 (e.g., in a front-to-back arrangement). The semiconductor die 404 and the additional semiconductor die can be coupled through hybrid bonding. Thermally conductive material of the additional semiconductor die can be aligned with the thermally conductive material 422 of the semiconductor die 404. The thermally conductive material 422 or the thermally conductive material of the additional semiconductor die can be heated (e.g., to a temperature greater than 300 degrees Celsius) such that the thermally conductive material 422 and the thermally conductive material of the additional semiconductor die directly bond (e.g., a metal-metal bond) to form interconnects. In some cases, the layer of dielectric material 416 can bond with a layer of dielectric material on the additional semiconductor die.

### Thermally Dissipative Encapsulant

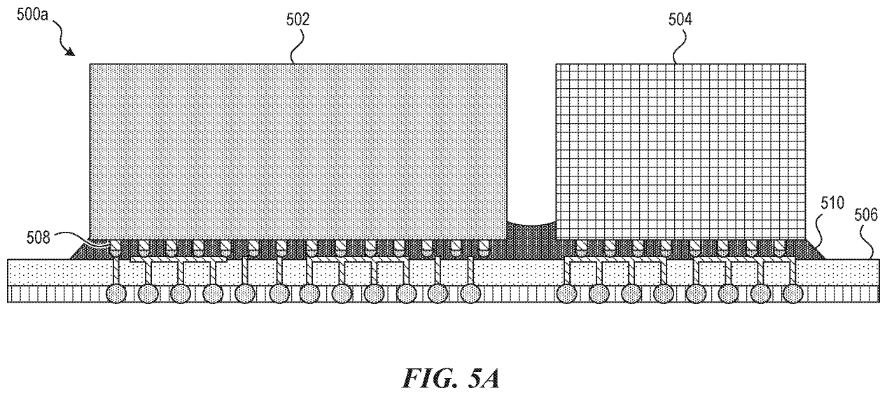

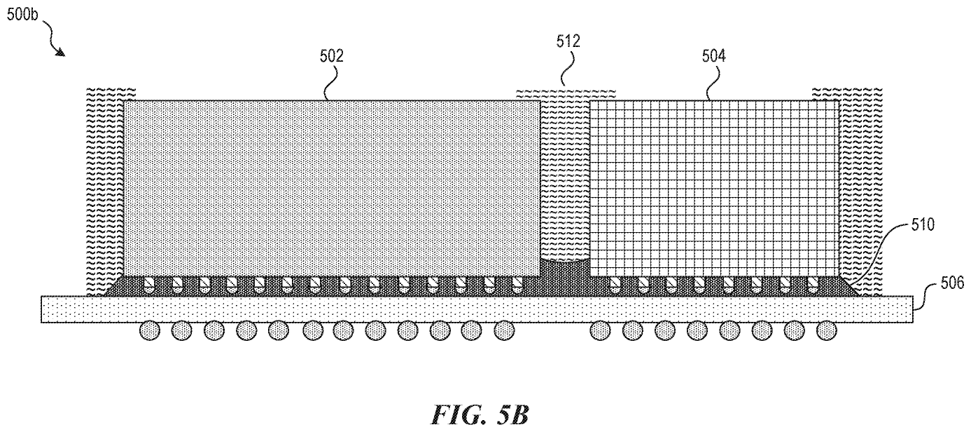

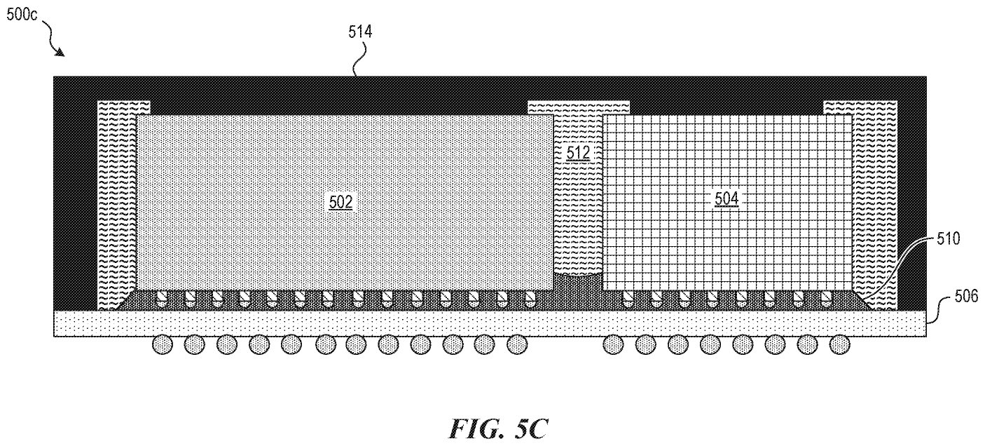

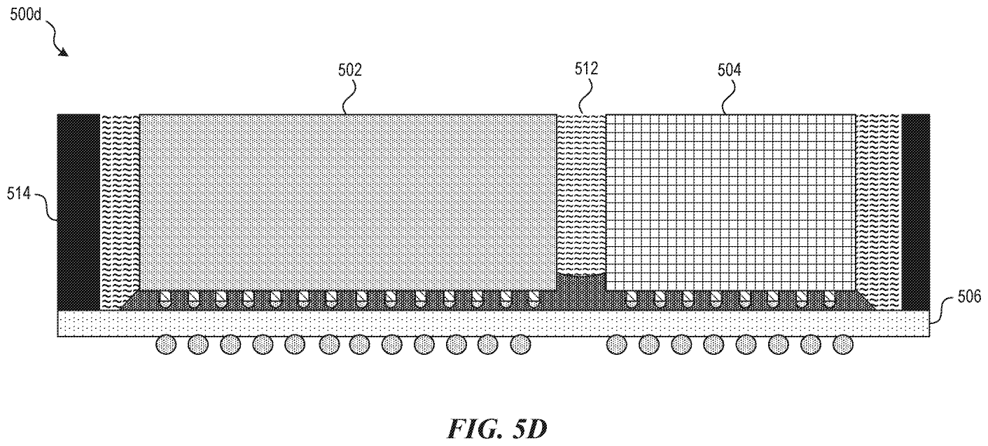

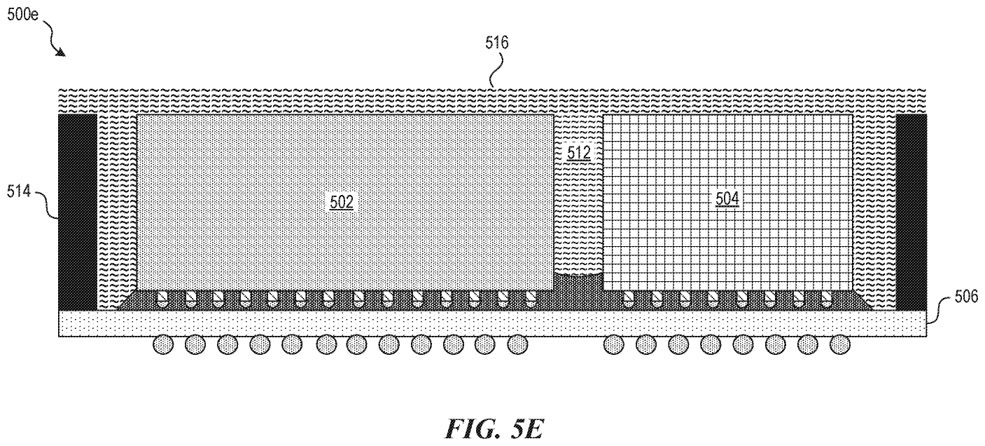

In accordance with some embodiments of the present technology, thermally conductive material can be used to at least partially encapsulate a semiconductor device assembly. FIGS. 5A-5E illustrate simplified schematic cross-sectional views of steps for fabricating one such semiconductor device assembly. Specifically, FIG. 5A illustrates a simplified schematic cross-sectional view of a semiconductor device assembly 500a that includes at least one semiconductor die 502 (e.g., logic die) and at least one semiconductor die 504 (e.g., memory die) coupled to a substrate 506 (e.g., PCB, interposer, semiconductor wafer, semiconductor die). The semiconductor die 502 can couple to the substrate 506 at a first lateral location and the semiconductor die 504 can couple to the substrate 506 at a second lateral location different from the first lateral location. In some cases, the at least one semiconductor die 502 can include a graphics processing unit (GPU), a central processing unit (CPU), an application specific integrated circuit (ASIC), a system-on-chip (SoC), or the like. The at least one semiconductor die 504 can include a stack of memory dies that, for example, implement a high-bandwidth memory (HBM) device. In some implementations, the substrate 506 can be a wafer-level or panel-level substrate with multiple semiconductor dies coupled to the substrate 506 at different locations. In this way, the substrate 506 can be diced to produce multiple packaged semiconductor devices.

Interconnects 508 (e.g., solder, conductive pillars) can be formed between the semiconductor die 502 and the substrate 506 or the semiconductor die 504 and the substrate 506 to electrically couple the components. The substrate 506 can include traces, lines, vias, and other connective elements that provide external connectivity (e.g., power, ground, I/O signaling) to the semiconductor die 502 or the semiconductor die 504 (e.g., through solder balls). An underfill material 510 (e.g., capillary underfill) can be disposed between the semiconductor die 502 and the substrate 506 or the semiconductor die 504 and the substrate 506 to electrically insulate the interconnects 508 and mechanically support the semiconductor device assembly 500a. In aspects, the underfill material 510 can prevent the thermally conductive material disposed in FIG. 5B from electrically contacting the interconnects 508.

FIG. 5B illustrates a simplified schematic cross-sectional view of a semiconductor device assembly 500b that includes thermally conductive material 512 (e.g., carbon nanotubes, graphene) disposed at least partially around the semiconductor die 502, the semiconductor die 504, or the substrate 506. In some cases, the thermally conductive material 512 is not disposed over the entire substrate 506 (e.g., to not interfere with dicing lanes). The thermally conductive material 512 can be dispensed in a liquid form onto the substrate 506 or the underfill material 510 such that the thermally conductive material 512 extends along a side of the semiconductor die 502 or the semiconductor die 504. In this way, the thermally conductive material 512 can have a viscosity that enables substantially vertical deposition (e.g., within 10 degrees, within 5 degrees, within 1 degree). The thermally conductive material 512 can be disposed between the semiconductor die 502 and the semiconductor die 504. In some implementations, a mold can be placed around the semiconductor device assembly, and the thermally conductive material 512 can be dispensed into the mold. In some cases, the thermally conductive material 512 can extend over at least a portion of an upper surface of the semiconductor die 502 or the semiconductor die 504. In doing so, the thermally conductive material 512 can extend entirely up the side of the semiconductor die 502 or the semiconductor die 504 and overflow onto the upper surface. A mold can then be disposed over the semiconductor device assembly 500b, as illustrated in FIG. 5C.

FIG. 5C illustrates a simplified schematic cross-sectional view of a semiconductor device assembly 500c that includes a mold 514 (e.g., epoxy mold compound (EMC)) at least partially surrounding the thermally conductive material 512, the semiconductor die 502, the semiconductor die 504, or the substrate 506. The mold 514 can be disposed at the substrate 506 at locations not covered by the thermally conductive material 512 (e.g., near dicing lanes). In aspects, the mold 514 can be disposed over an upper portion of the thermally conductive material 512 or over an exposed upper surface of the semiconductor die 502 or the semiconductor die 504 not covered by the thermally conductive material 512. An upper surface of the mold 514 and the thermally conductive material 512 can then be grinded to expose an upper surface of the semiconductor die 502 or the semiconductor die 504, as illustrated in FIG. 5D.

FIG. 5D illustrates a simplified schematic cross-sectional view of a semiconductor device assembly 500d after the mold 514 and the thermally conductive material 512 have been removed from the upper surface of the semiconductor die 502 or the semiconductor die 504. In aspects, the mold 514 or the thermally conductive material 512 can be removed through chemical-mechanical planarization (CMP). After the upper portion of the mold 514 is removed, the remaining portion of the mold 514 can be located along dicing lanes of the substrate 506. In this way, the mold 514 can provide a solid dicing lane such that the substrate 506 can be diced to singulate the multiple semiconductor device packages. The resulting singulated semiconductor device assembly can include sidewalls formed from the mold 514 that at least partially surround the thermally conductive material 512. Additionally, the thermally conductive material 512 and the semiconductor die 502 or the semiconductor die 504 can be exposed at an upper surface to enable additional heat dissipating features to be implemented, as illustrated in FIG. 5E.

FIG. 5E illustrates a simplified schematic cross-sectional view of a semiconductor device assembly 500e after thermally conductive material 516 has been disposed (e.g., at the package level) at the upper surface of the thermally conductive material 512 and the semiconductor die 502 or the semiconductor die 504. The thermally conductive material 516 (e.g., a same or different material than the thermally conductive material 512) can be disposed (e.g., dispensed) in a layer at the upper surface. In this way, heat can dissipate from the semiconductor die 502, the semiconductor die 504, or the thermally conductive material 512 through the thermally conductive material 516. In some cases, the thermally conductive material 516 can extend at least partially over the mold 514. In general, however, the thermally conductive material 512 or the thermally conductive material 516 can at least partially encapsulate the semiconductor die 502, the semiconductor die 504, or the substrate 506 and improve heat dissipation from the semiconductor device assembly 500e.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-5E could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

### Example Systems

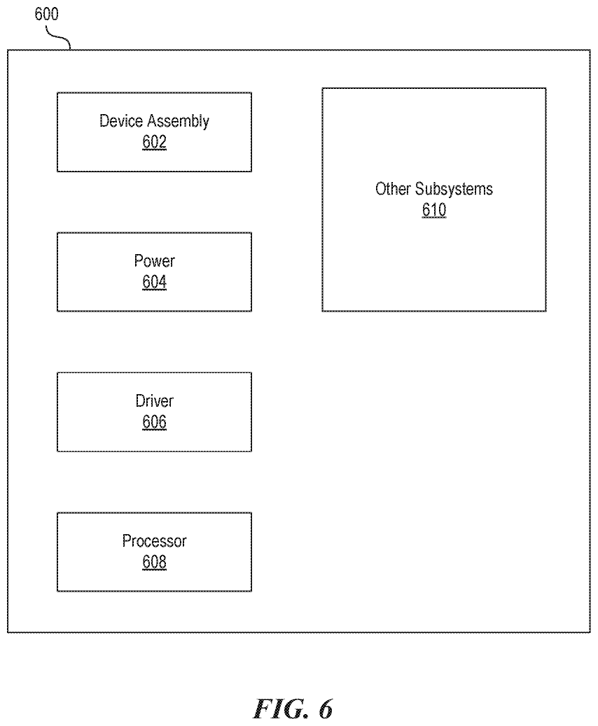

Any one of the semiconductor devices and semiconductor device assemblies described above with reference to FIGS. 1-5E can be incorporated into any of a myriad of larger and/or more complex systems, a representative example of which is system 600 shown schematically in FIG. 6. The system 600 can include a semiconductor device assembly 602 (e.g., a discrete semiconductor device), a power source 604, a driver 606, a processor 608, and/or other subsystems or components 610. The semiconductor device assembly 602 can include features generally similar to those of the semiconductor device assemblies described above with reference to FIGS. 1-5E. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, vehicles, appliances, and other products. Components of the system 600 can be housed in a single unit or distributed over multiple, interconnected units (e.g., through a communications network). The components of the system 600 can also include remote devices and any of a wide variety of computer-readable media.

### Example Methods

This disclosure now turns to various methods for fabricating semiconductor device assemblies in accordance with one or more embodiments of the present technology. Although illustrated in a particular configuration, operations within any of the methods may be omitted, repeated, or reorganized. Moreover, any of the methods may include additional operations, for example, those detailed in one or more other methods described herein.

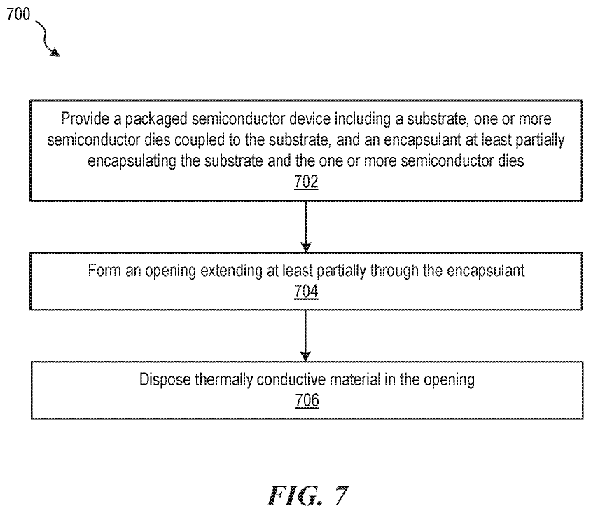

FIG. 7 illustrates a method 700 of fabricating a semiconductor device assembly that includes a thermally conductive via extending through an encapsulant. At 702, a packaged semiconductor device is provided. The packaged semiconductor device includes a substrate (e.g., a PCB, an interposer, a semiconductor die), one or more semiconductor dies coupled to the substrate, and an encapsulant (e.g., mold resin) at least partially encapsulating the substrate and the one or more semiconductor dies. At 704, an opening that extends at least partially through the encapsulant is formed. For example, the opening can extend from an upper surface of the encapsulant to the substrate or to one of the one or more semiconductor dies. In some implementations, the opening can be formed through drilling (e.g., laser drilling). At 706, thermally conductive material is disposed in the opening. The thermally conductive material can include carbon nanotubes or graphene. The thermally conductive material can be dispensed in a liquid form into the opening. In doing so, thermally conductive through-encapsulant vias can be formed that enable heat dissipation away from the packaged semiconductor device. In some cases, a heat dissipating structure can be disposed on the packaged semiconductor device in contact with the thermally conductive material. In this way, heat can dissipate from the packaged semiconductor device through a larger surface, thereby increasing the rate of heat dissipation.

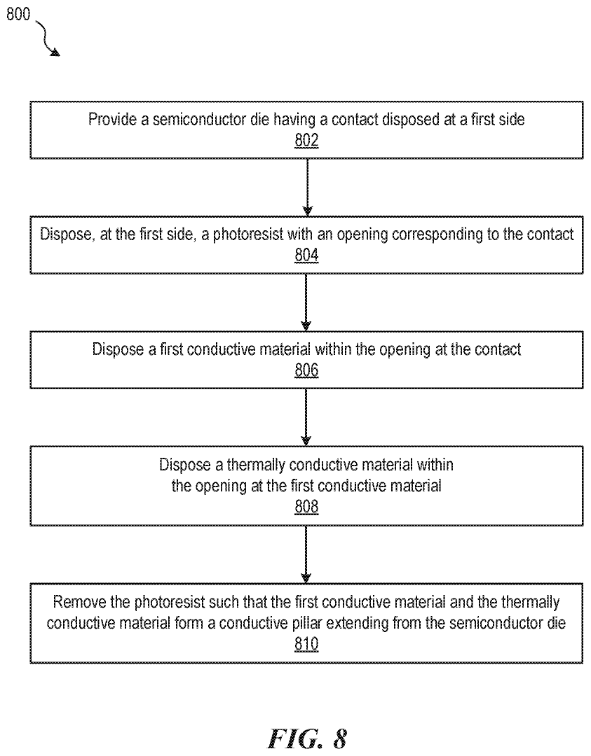

FIG. 8 illustrates a method 800 of fabricating a semiconductor device assembly that includes thermally conductive material implemented within a conductive pillar. At 802, a semiconductor die having a contact disposed at a first side is provided. At 804, a photoresist having an opening corresponding to the contact is disposed at the first side. At 806, a first conductive material (e.g., copper) is disposed (e.g., using CVD) within the opening and at the contact. At 808, thermally conductive material (e.g., carbon nanotubes, graphene) is disposed (e.g., dispensed) within the opening at the first conductive material. In some cases, solder may be disposed within the opening. At 810, the photoresist is removed such that the first conductive material and the thermally conductive material form a conductive pillar extending from the semiconductor die.

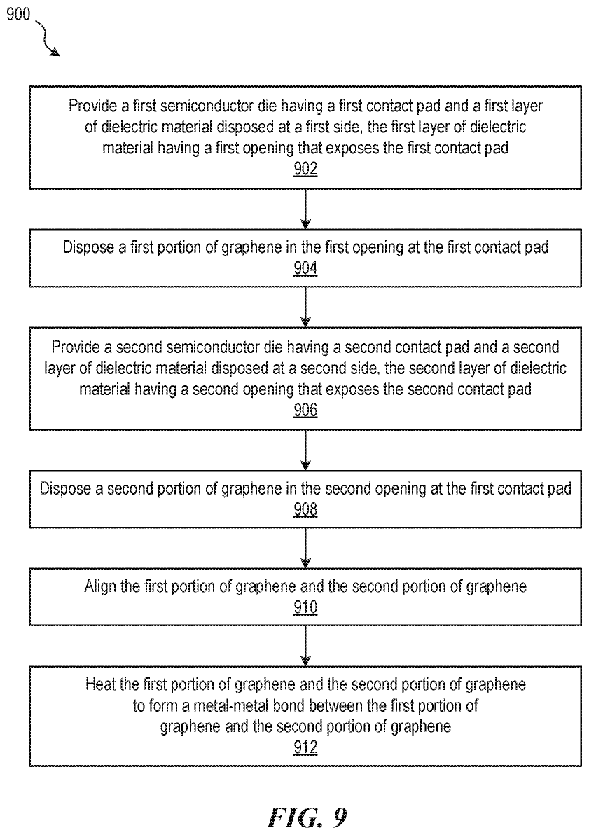

FIG. 9 illustrates a method 900 of fabricating a semiconductor device assembly that includes interconnects formed from thermally conductive material. At 902, a first semiconductor die is provided. The first semiconductor die includes a first contact pad (e.g., copper pad) and a first layer of dielectric material disposed at a first side. The layer of dielectric material has a first opening that exposes the first contact pad. At 904, a first portion of graphene is disposed (e.g., dispensed) in the first opening at the first contact pad. At 906, a second semiconductor die is provided. The second semiconductor die includes a second contact pad and a second layer of dielectric material disposed at a second side. The second layer of dielectric material has a second opening that exposes the second contact pad. At 908, a second portion of graphene is disposed in the second opening at the first contact pad. At 910, the first portion of graphene and the second portion of graphene are aligned. At 912, the first portion of graphene and the second portion of graphene are heated to form a metal-metal bond (e.g., hybrid bond) between the first portion of graphene and the second portion of graphene.

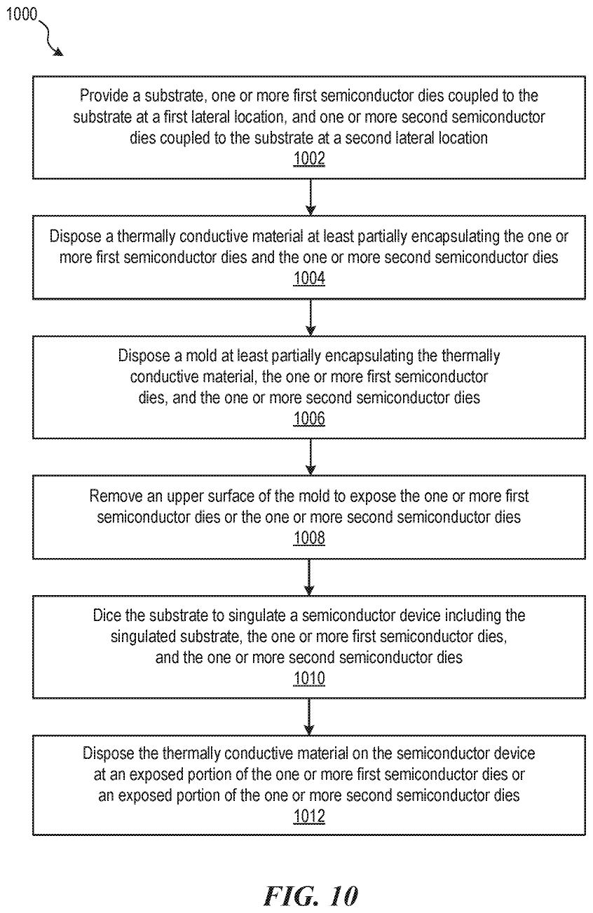

FIG. 10 illustrates a method 1000 of fabricating a semiconductor device assembly that includes a thermally conductive encapsulant. At 1002, a substrate, one or more first semiconductor dies coupled to the substrate at a first lateral location, and one or more second semiconductor dies coupled to the substrate at a second lateral location are provided. At 1004, a thermally conductive material (e.g., carbon nanotubes, graphene) is disposed. The thermally conductive material at least partially encapsulates the one or more first semiconductor dies and the one or more second semiconductor dies. At 1006, a mold is disposed at least partially encapsulating the thermally conductive material, the one or more first semiconductor dies, and the one or more second semiconductor dies. At 1008, an upper surface of the mold is removed to expose the one or more first semiconductor dies or the one or more second semiconductor dies. At 1010, the substrate is diced to singulate a semiconductor device that includes the singulated substrate, the one or more first semiconductor dies, and the one or more second semiconductor dies. At 1012, the thermally conductive material is disposed on the semiconductor device at an exposed portion of the one or more first semiconductor dies or an exposed portion of the one or more second semiconductor dies.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using CVD, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3D1) applications.

The devices discussed herein, including a memory device, can be formed on a semiconductor substrate or die, such as silicon, germanium, silicon-germanium alloy, gallium arsenide, gallium nitride, etc. In some cases, the substrate is a semiconductor wafer. In other cases, the substrate can be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, can be controlled through doping using various chemical species including, but not limited to, phosphorous, boron, or arsenic. Doping can be performed during the initial formation or growth of the substrate, by ion-implantation, or by any other doping means.

The functions described herein can be implemented in hardware, software executed by a processor, firmware, or any combination thereof. Other examples and implementations are within the scope of the disclosure and appended claims. Features implementing functions can also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications can be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate;
one or more semiconductor dies coupled to the substrate;
an encapsulant at least partially encapsulating the substrate and the one or more semiconductor dies; and
a portion of thermally conductive material extending at least partially through the encapsulant from an upper surface of the encapsulant, the thermally conductive material comprising carbon nanotubes or graphene.

2. The semiconductor device assembly of claim 1, further comprising a heat dissipating structure disposed at the upper surface of the encapsulant in contact with the portion of thermally conductive material.

3. The semiconductor device assembly of claim 1, wherein the portion of thermally conductive material extends from the upper surface of the encapsulant to the substrate.

4. The semiconductor device assembly of claim 1, wherein the portion of thermally conductive material extends from the upper surface of the encapsulant to one of the one or more semiconductor dies.

5. The semiconductor device assembly of claim 1, wherein the portion of thermally conductive material is tapered from the upper surface of the encapsulant.

6. A semiconductor device assembly, comprising:
a substrate having a first contact disposed at a first side;
a semiconductor die having a second contact disposed at a second side and corresponding to the first contact; and
a conductive pillar extending between the second contact and the first contact to electrically couple the substrate and the semiconductor die,
wherein the conductive pillar comprises a first conductive material and a portion of thermally conductive material at least partially enclosed within the first conductive material, the thermally conductive material including carbon nanotubes or graphene.

7. The semiconductor device assembly of claim 6, wherein the portion of thermally conductive material is tapered toward the first contact.

8. The semiconductor device assembly of claim 6, wherein the portion of thermally conductive material is covered by the first conductive material at a distal portion of the conductive pillar opposite the semiconductor die.

9. The semiconductor device assembly of claim 6, wherein the portion of thermally conductive material is entirely enclosed within the first conductive material.

10. The semiconductor device assembly of claim 6, wherein the semiconductor die further includes a third contact disposed at a third side opposite the second side and a through-silicon via extending between the second contact and the third contact, the semiconductor device assembly further comprising:
an additional semiconductor die having a fourth contact disposed at a fourth side and corresponding to the third contact; and
an additional conductive pillar extending between the fourth contact and the third contact to electrically couple the semiconductor die and the additional semiconductor die,
wherein the additional conductive pillar comprises a second conductive material and a second portion of thermally conductive material at least partially enclosed within the second conductive material.

11. The semiconductor device assembly of claim 6, further comprising solder disposed at a distal portion of the conductive pillar opposite the semiconductor die.

12. A semiconductor device assembly, comprising:
a first semiconductor die comprising:
a first layer of dielectric material disposed at a first side of the first semiconductor die;
a first contact pad disposed at the first side of the first semiconductor die and within a first opening in the first layer of dielectric material; and
a first portion of graphene disposed at the first contact pad and within the first opening; and
a second semiconductor die coupled to the first semiconductor die, the second semiconductor die comprising:
a second layer of dielectric material disposed at a second side of the second semiconductor die;
a second contact pad disposed at the second side of the second semiconductor die and within a second opening in the second layer of dielectric material; and
a second portion of graphene disposed at the second contact pad and within the second opening,
wherein the first portion of graphene is directly bonded with the second portion of graphene such that the first semiconductor die and the second semiconductor die are electrically coupled through the first contact pad and the second contact pad.

13. The semiconductor device assembly of claim 12, wherein:
the second semiconductor die further comprises:
a third layer of dielectric material disposed at a third side of the second semiconductor die opposite the second side;
a third contact pad disposed at the third side and within a third opening in the third layer of dielectric material;
a third portion of graphene disposed at the third contact pad and within the third opening; and
a through-silicon via extending between the second contact pad and the third contact pad,
wherein the semiconductor device assembly further comprises:
a third semiconductor die coupled to the second semiconductor die, the third semiconductor die comprising:
a fourth layer of dielectric material disposed at a fourth side of the third semiconductor die;
a fourth contact pad disposed at the fourth side of the third semiconductor die and within a fourth opening in the fourth layer of dielectric material; and
a fourth portion of graphene disposed at the fourth contact pad and within the fourth opening,
wherein the third portion of graphene is directly bonded with the fourth portion of graphene such that the second semiconductor die and the third semiconductor die are electrically coupled through the third contact pad and the fourth contact pad.

14. The semiconductor device assembly of claim 12, wherein the first contact pad comprises a copper pad.

15. The semiconductor device assembly of claim 12, wherein the first layer of dielectric material is directly bonded with the second layer of dielectric material.

16. A semiconductor device assembly, comprising:
a substrate;
one or more first semiconductor dies coupled to the substrate at a first lateral location;
one or more second semiconductor dies coupled to the substrate at a second lateral location different from the first lateral location;
a thermally conductive material at least partially encapsulating the one or more first semiconductor dies, the one or more second semiconductor dies, and the substrate, the thermally conductive material comprising carbon nanotubes or graphene; and
molded sidewalls at least partially surrounding the thermally conductive material.

17. The semiconductor device assembly of claim 16, wherein:
the one or more first semiconductor dies comprise one or more logic dies; and
the one or more second semiconductor dies comprise one or more memory dies.

18. The semiconductor device assembly of claim 16, wherein the thermally conductive material is disposed over an upper surface of the one or more first semiconductor dies opposite the substrate or an upper surface of the one or more second semiconductor dies opposite the substrate.

19. The semiconductor device assembly of claim 16, wherein the thermally conductive material is disposed over an upper surface of the molded sidewall opposite the substrate.

20. The semiconductor device assembly of claim 16, further comprising:
an underfill material disposed between the substrate and the one or more first semiconductor dies or the substrate and the one or more second semiconductor dies,
wherein the underfill material separates at least a portion of the thermally conductive material from interconnects coupling the one or more first semiconductor dies to the substrate or interconnects coupling the one or more second semiconductor dies to the substrate.
